(19) United States
(12) Patent Application Publication
(10) Pub. No.: US 2006/0145237 A1
(43) Pub. Date: Jul. 6, 2006

(54) Non-volatile memory device and method of manufacturing the same

(75) Inventors: Byoung-Ho Kim, Suwon-si (KR); Seung-Beom Yoon, Suwon-si (KR); Weon-Ho Park, Suwon-si (KR); Ji-Do Ryu, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/324,415

(22) Filed: Jan. 3, 2006

(30) Foreign Application Priority Data
Jan. 4, 2005 (KR) 10-2005-0000493

(51) Int. Cl. H01L 29/76

(52) U.S. Cl. 257/314

(57) ABSTRACT

Provided are a non-volatile memory device and a method of manufacturing the same. The non-volatile memory device includes a gate insulating layer having a tunneling window formed therein. The tunneling window has a predetermined width parallel to a channel length direction and has a predetermined length perpendicular to the channel length direction on a semiconductor substrate. The non-volatile memory device further includes a lower floating gate including a first lower floating gate formed on the gate insulating layer and a second lower floating gate spaced a predetermined interval apart from the first lower floating gate, and wherein the tunneling window and a portion of the gate insulating layer which is adjacent to the tunneling window are partially exposed in a region between the first lower floating gate and the second lower floating gate. Moreover, the non-volatile memory device includes a tunneling insulating layer formed on the tunneling window, an upper floating gate which is formed on the lower floating gate and the tunneling insulating layer and fills the region between the first lower floating gate and the second lower floating gate. Additionally, the non-volatile memory device includes an inter-gate insulating layer formed on the upper floating gate, and a memory transistor having a control line formed on the gate insulating layer.

This application claims priority from Korean Patent Application No. 10-2005-0000493 filed on Jan. 4, 2005 in the Korean Intellectual Property Office, the disclosure of which is incorporated by reference herein in its entirety.

### BACKGROUND OF THE INVENTION

1. Field of the Invention

The present invention relates to a non-volatile memory device and to a method of manufacturing the same, and more particularly, to a non-volatile memory device having improved operating characteristics by reducing an area of a tunneling window and to a method of manufacturing the same.

2. Description of the Related Art

In electrically erasable programmable read only memory (EEPROM) devices, electrons pass through a thin insulating tunneling layer made of, for example, silicon dioxide (SiO₂), and electric charges accumulate in a floating gate by Fowller-Nodheim tunneling (hereinafter, referred to as ‘FN tunneling’). The amount of electric charges accumulating in the floating gate varies the threshold voltage of a transistor. Moreover, by applying a voltage lower than the threshold voltage to the transistor, one may determine whether the transistor is turned on or off or whether a programming operation is on or off.

In an attempt to obtain EEPROM devices which have higher-speed, higher-functionality, and lower-power-consumption characteristics, much effort has been made in the industry to shrink feature sizes of the EEPROM devices but without also compromising their operating capabilities. The reason why smaller sizes for certain features of an EEPROM device plays a role in improving operational characteristics of these devices will be explained below.

For example, during a programming operation of a memory cell, a high voltage is applied to a control line while a common source is floated and a drain is grounded, thereby charging a floating gate.

In addition, during an erasing operation, a high voltage is applied to the drain while the common source is floated and the control line is grounded, thereby discharging the floating gate.

Moreover, electric charges move through a tunneling insulating layer formed in a tunneling window of the EEPROM devices, and thus the size and profile of a tunneling insulating layer are factors in determining characteristics of the devices. Accordingly, as the size of EEPROM device features continue to shrink, scaling-down of the tunneling insulating layer of these devices becomes a relevant issue.

Conventional tunneling insulating layers are generally manufactured in the following manner. First, a gate insulating layer is formed on a semiconductor substrate. Next, a photoresist pattern having an exposed region in which a tunneling window is to be formed is then formed by a photolithography process. The tunneling window is then formed by performing wet etching along the photoresist pattern. Further, a tunneling insulating layer is grown on the tunneling window to a thickness that is less than that of the gate insulating layer.

However, a difficulty with conventional non-volatile memory device fabricatrion processes is that typically since a potential region of a tunneling window is directly patterned by a photolithography process, the size of the tunneling window is also determined by performance of the photolithography process, thereby limiting the improvement of the operational characteristics of the memory cell.

### SUMMARY OF THE INVENTION

According to an exemplary embodiment of the present invention, a non-volatile memory device is provided. The non-volatile memory device includes a gate insulating layer having a tunneling window formed therein. The tunneling window has a predetermined width parallel to a channel length direction and has a predetermined length perpendicular to the channel length direction on a semiconductor substrate. The non-volatile memory device further includes a lower floating gate including a first lower floating gate formed on the gate insulating layer and a second lower floating gate spaced a predetermined interval apart from the first lower floating gate, and wherein the tunneling window and a portion of the gate insulating layer adjacent to the tunneling window are partially exposed in a region between the first lower floating gate and the second lower floating gate. Moreover, the non-volatile memory device also includes a tunneling insulating layer formed on the tunneling window, an upper floating gate which is formed on the lower floating gate and the tunneling insulating layer and fills the region between the first lower floating gate and the second lower floating gate, an inter-gate insulating layer formed on the upper floating gate, and a memory transistor having a control line formed on the gate insulating layer.

According to another exemplary embodiment of the present invention, a non-volatile memory device is provided. The non-volatile memory device includes a gate insulating layer having a tunneling window formed therein. The tunnel window has a predetermined width parallel to a channel length direction and has a predetermined length perpendicular to the channel length direction on a semiconductor substrate. The non-volatile memory device further includes a lower floating gate having an opening which has a predetermined length parallel to a direction of the length of the tunneling window and partially exposes the tunneling window and a portion of the gate insulating layer which is adjacent to the tunneling window, a tunneling insulating layer formed on the tunneling window exposed by the opening, an upper floating gate which is formed on the lower floating gate and the tunneling insulating layer and fills the opening, an inter-gate insulating layer formed on the upper floating gate, and a memory transistor including a control line formed on the inter-gate insulating layer.

According to still another exemplary embodiment of the present invention, a method of manufacturing a non-volatile memory device is provided. The method includes forming a gate insulating layer that provides a tunneling window with a region having a predetermined width parallel to a channel length direction and having a predetermined length perpendicular to the channel length direction on a semiconductor substrate, forming a first-conductive-layer pattern on the gate insulating layer including a first-conductive-layer first pattern and a first-conductive-layer second pattern that are separated from each other by a predetermined interval to partially expose the region in which the tunneling window is to be formed and a portion of the gate insulating layer adjacent to the region. The method further includes forming a first impurity region in a region between the first-conductive-layer first pattern and the first-conductive-layer second pattern on the semiconductor substrate, forming the tunneling window by selectively removing the gate insulating layer in the region in which the tunneling window is to be formed from the portion of the gate insulating layer exposed between the first-conductive-layer first pattern and the first-conductive-layer second pattern, forming the tunneling insulating layer on the tunneling window, forming a second conductive layer on the first-conductive-layer pattern and the tunneling insulating layer to fill the region between the first-conductive-layer first pattern and the first-conductive-layer second pattern, patterning the first-conductive-layer pattern and the second conductive layer in a channel length direction, forming a third conductive layer that is insulated from the first-conductive-layer pattern and the second conductive layer, and forming a lower floating gate, an upper floating gate, and a control line by patterning the first-conductive-layer pattern, the second conductive layer, and the third conductive layer in a direction perpendicular to the channel length direction.

### BRIEF DESCRIPTION OF THE DRAWINGS

FIG. 1 is a layout view of a non-volatile memory device according to an exemplary embodiment of the present invention;

FIGS. 2 through 4 are sectional views of the non-volatile memory device, taken along lines II-II′, III-III′, and IV-IV′ of FIG. 1;

FIG. 5 is a sectional view of a non-volatile memory device according to an exemplary embodiment of the present invention;

FIG. 6 is a sectional view of a non-volatile memory device according to an exemplary embodiment of the present invention;

FIG. 7 is a layout view of a non-volatile memory device according to an exemplary embodiment of the present invention;

FIG. 8 is a layout view of a non-volatile memory device according to an exemplary embodiment of the present invention;

FIG. 9 is a sectional view of the non-volatile memory device, taken along a line IX-IX′ of FIG. 8;

FIG. 10A is a layout view for illustrating a method of manufacturing the non-volatile memory device shown in FIG. 1;

FIGS. 10B through 10D are sectional views of the non-volatile memory device, taken along lines B-B′, C-C′, and D-D′ of FIG. 10A;

FIG. 11A is a layout view for illustrating a method of manufacturing the non-volatile memory device shown in FIG. 1;

FIGS. 11B through 11D are sectional views of the non-volatile memory device, taken along lines B-B′, C-C′, and D-D′ of FIG. 11A;

FIG. 12A is a layout view for illustrating a method of manufacturing the non-volatile memory device shown in FIG. 1;

FIGS. 12B through 12D are sectional views of the non-volatile memory device, taken along lines B-B′, C-C′, and D-D′ of FIG. 12A;

FIG. 13A is a layout view for illustrating a method of manufacturing the non-volatile memory device shown in FIG. 1;

FIGS. 13B through 13D are sectional views of the non-volatile memory device, taken along lines B-B′, C-C′, and D-D′ of FIG. 13A;

FIG. 14A is a layout view for illustrating a method of manufacturing the non-volatile memory device shown in FIG. 1;

FIGS. 14B through 14D are sectional views of the non-volatile memory device, taken along lines B-B′, C-C′, and D-D′ of FIG. 14A;

FIG. 15A is a layout view for illustrating a method of manufacturing the non-volatile memory device shown in FIG. 1;

FIGS. 15B through 15D are sectional views of the non-volatile memory device, taken along lines B-B′, C-C′, and D-D′ of FIG. 15A;

FIGS. 16 and 17 are sectional views for illustrating a method of manufacturing the non-volatile memory device shown in FIG. 6;

FIG. 18A is a layout view for illustrating a method of manufacturing the non-volatile memory device shown in FIG. 8;

FIGS. 18B through 18D are sectional views of the non-volatile memory device, taken along lines B-B′, C-C′, and D-D′ of FIG. 18A;

FIG. 19A is a layout view for illustrating a method of manufacturing the non-volatile memory device shown in FIG. 8;

FIGS. 19B through 19D are sectional views of the non-volatile memory device, taken along lines B-B′, C-C′, and D-D′ of FIG. 19A;

FIG. 20A is a layout view for illustrating a method of manufacturing the non-volatile memory device shown in FIG. 8; and

FIGS. 20B through 20D are sectional views of the non-volatile memory device, taken along lines B-B′, C-C′, and D-D′ of FIG. 20A.

### DETAILED DESCRIPTION OF THE EXEMPLARY EMBODIMENTS OF THE INVENTION

Features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Like reference numerals refer to like elements throughout the specification.

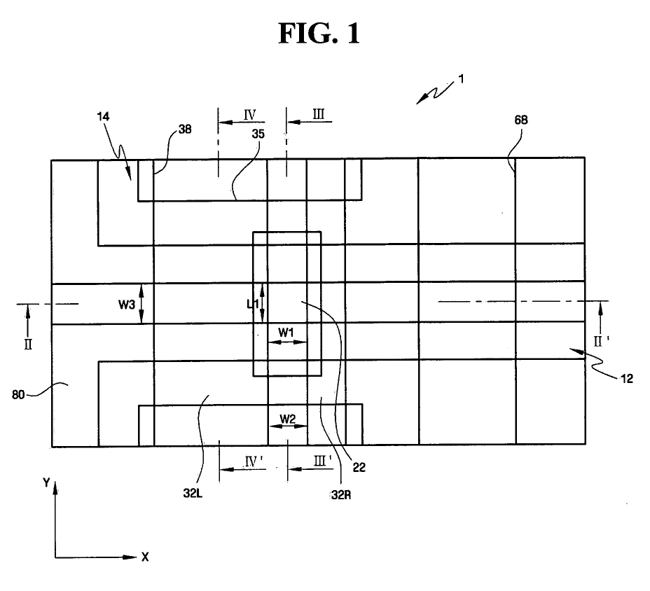

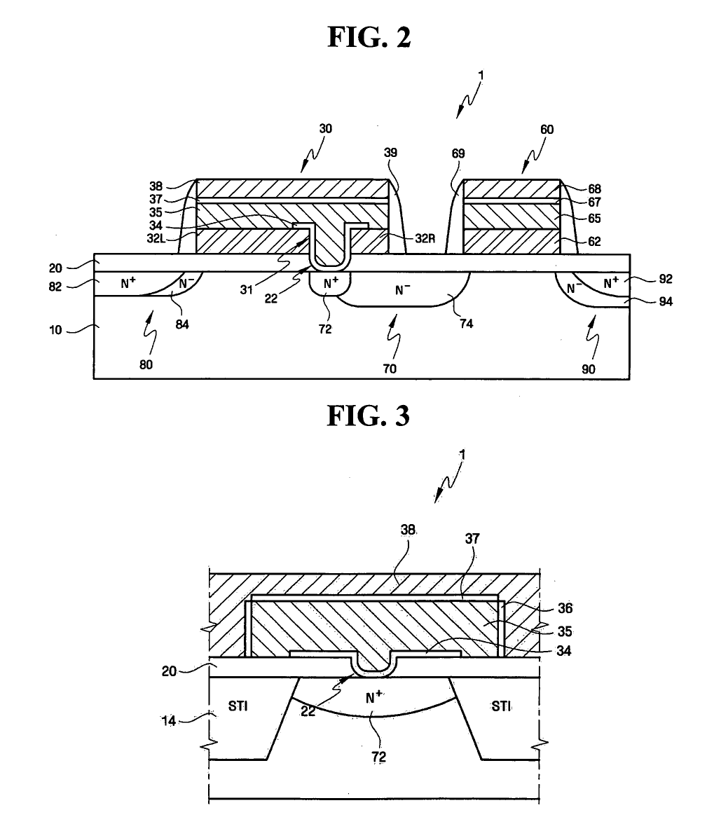

FIG. 1 is a layout view of a non-volatile memory device according to an exemplary embodiment of the present invention, and FIGS. 2 through 4 are sectional views of the non-volatile memory device, taken along lines II-II′, III-III′, and IV-IV′ of FIG. 1.

Referring to FIGS. 1 through 4, a non-volatile memory device 1 according to an exemplary embodiment of the present invention includes a semiconductor substrate 10, a gate insulating layer 20, a memory transistor 30, a select transistor 60, and first through third impurity regions 70 through 90.

The semiconductor substrate 10 includes an active region 12 and a device isolation region 14. The memory transistor 30, the select transistor 60, and the first through third impurity regions 70 through 90 are formed on the active region 12. The device isolation region 14 may be a shallow trench isolation (STI) region that defines the active region 12. The device isolation region 14 may be a field oxide (FOX) region formed by a local oxidation of silicon (LOCOS) method. The semiconductor substrate 10 may be formed of at least one semiconductor material selected from a group of silicon (Si), germanium (Ge), silicon germanium (SiGe), gallium phosphide (GaP), gallium arsenide (GaAs), silicon carbide (SiC), silicon germanium carbon (SiGeC), indium arsenide (InAs), and indium phosphide (InP).

The gate insulating layer 20 is formed on the semiconductor substrate 10 and has a thickness of about 200 to about 500 angstroms (Å). The gate insulating layer 20 is formed of silicon dioxide (SiO₂), silicon oxynitride (SiON), silicon nitride (Si₃N₄), germanium oxynitride (GeₓO_{y}N_{z},) germanium silicon oxide (GexSi_{y}O_{z}), a high dielectric constant (k) material, or a combination thereof. Here, the high-k material is formed of hafnia (HfO₂), zirconia (ZrO₂), aluminum oxide (Al₂O₃), tantalum oxide (Ta₂O₅), hafnium silicate, or zirconium silicate, or a combination thereof by an atomic layer deposition (ALD) method. As the thickness of the gate insulating layer 20 decreases, a high-k material should preferably be used.

In a predetermined region of the active region 12 on the gate insulating layer 20, a tunneling window 22 is formed having a predetermined width W1 parallel to a channel length direction X and a predetermined length L1 parallel to a direction Y perpendicular to the channel length direction X. The tunneling window 22 is formed by a first etching process which includes patterning a first conductive layer to separate the first conductive layer by a predetermined interval, e.g., an interval that is substantially the same as the width W1 of the tunneling window 22 and also by a second etching process which includes patterning the first conductive layer using a photoresist pattern that exposes an interval that is substantially the same as the length L1 of the tunneling window 22. Moreover, in the second etching process, according to the present exemplary embodiment of the invention, a plurality of memory cells adjacent in the direction Y perpendicular to the channel length direction X are collectively etched in the first etching process and a plurality of memory cells adjacent in the channel length direction X are collectively etched.

However, with conventional non-volatile memory devices and processes, since the region in which a tunneling window is to be formed is directly patterned, the size of the tunneling window is determined by the performance of a photolithography process, thereby making it difficult to improve the operating characteristics of a memory cell. In contrast, according to the present exemplary embodiment of the invention, the tunneling window 22 is stably formed in a region that is commonly etched by both of the two etching processes. Furthermore, the size of the tunneling window 22 formed according to the present exemplary embodiment is less restricted by the performance of a photolithography process in comparison to conventional methods of manufacturing non-volatile memory devices. For example, with the present exemplary embodiment, only the width W1 of the tunneling window 22 may be restricted by the performance of the photolithography process in the first etching process and only the length L1 of the tunneling window 22 may be restricted by the performance of a photolithography process in the second etching process.

As discussed above, the tunneling window 22 according to an exemplary embodiment of the present invention is formed by two etching processes. Moreover, the tunneling window 22 is preferably formed in the shape of a rectangle having the width W1 and the length L1. Alternatively, the tunneling window 22 may be formed in a shape having a predetermined curvature such as a circle or an ellipse.

Table 1 shows a program coupling ratio (Gpgm), an erase coupling ratio (Gers), a program voltage (Vpgm), and an erase voltage (Vers) according to the width W1 of the tunneling window 22. The program coupling ratio (Gpgm) and the erase coupling ratio (Gers) are defined as Equation 1:

$$Gpgm = \frac{Cono}{Ctot} , Gers = 1 - \frac{Ctun}{Ctot} \qquad ( 1 )$$

where Cono means a capacitance of a capacitor formed between an upper floating gate 35 and a control line 38 and Ctun means a capacitance of a capacitor formed between the upper floating gate 25 and the semiconductor substrate 10. In addition, Ctot means the sum of Cono, Ctun, and capacitances of all capacitors that can be formed in the memory transistor 30.

As is evident from Table 1, the program coupling ratio (Gpgm), the erase coupling ratio (Gers), the program voltage (Vpgm), and the erase voltage (Vers) increase as the width W1 of the tunneling window 22 decreases. For instance, when the width W1 of the tunneling window 22 is reduced from about 0.24 to about 0.14 μm, a margin of about about 0.7 V is additionally provided. Further, if the width W1 and the length L1 of the tunneling window 22 are reduced to reduce the area of the tunneling window 22, Ctun also decreases, thereby increasing the coupling ratio. Thus, the non-volatile memory device 1 according to the present exemplary embodiment of the invention can reduce the width W1 of the tunneling window 22 to about 0.14 μm or less.

TABLE 1

| Width (μm) | Gpgm | Gers | Vpgm (V) | Vers (V) |
|---|---|---|---|---|
| 0.24 | 0.93 | 0.71 | 13.9 | 12.1 |
| 0.22 | 0.94 | 0.72 | 14.1 | 12.2 |
| 0.20 | 0.95 | 0.73 | 14.2 | 12.4 |
| 0.18 | 0.96 | 0.74 | 14.4 | 12.5 |
| 0.16 | 0.97 | 0.74 | 14.5 | 12.6 |
| 0.14 | 0.97 | 0.75 | 14.6 | 12.7 |

The memory transistor 30 is formed on the active region 12 in which the tunneling window 22 is formed and has a stacked structure including a lower floating gate, a tunneling insulating layer 34, the upper floating gate 35, an inter-gate insulating layer 37, and the control line 38.

The lower floating gate includes the first lower floating gate 32L formed on the gate insulating layer 20 and the second lower floating gate 32R separated from the first lower floating gate 32L by a predetermined interval W2. Here, the tunneling window 22 and a portion or area of the gate insulating layer 20 which is adjacent to the tunneling window 22 are partially exposed in a region between the first lower floating gate 32L and the second lower floating gate 32R. The predetermined interval W2 is substantially the same as the width W1 of the tunneling window 22. The first lower floating gate 32L and the second lower floating gate 32R each are formed of n+ polysilicon, p+ polysilicon, or silicon geranium (SiGe) capable of changing a work function, or a combination thereof. The first lower floating gate 32L and the second lower floating gate 32R each have a thickness of about 500 to about 1500 angstroms (Å).

The tunneling insulating layer 34 is formed in the tunneling window 22 that is exposed in a region between the first lower floating gate 32L and the second lower floating gate 32R. Moreover, the tunneling insulating layer 34 is formed along profiles of the tunneling window 22 and the first and second lower floating gates 32L and 32R. Here, it is preferable that the tunneling insulating layer 34 cover as smaller portion of the first and second lower floating gates 32L and 32R as possible for improving electric characteristics.

The tunneling insulating layer 34 is formed of silicon dioxide (SiO₂), silicon oxynitride (SiON), silicon oxynitride (SiO₃N₄), germanium oxynitrude (GeₓO_{y}N_{z}), germanium silicon oxide (GeₓSi_{y}O_{z}), a high-k material, or a combination thereof. The tunneling insulating layer 34 is formed as a stacked structure in which at least two materials selected from the above examples are sequentially stacked. For example, an oxide layer (SiO₂) is formed through the following methods including but not limited to dry oxidation using oxygen (O₂) gas at a temperature of about 750 to about 1100° C., wet oxidation in a vapor atmosphere at a temperature of about 750 to about 100° C., hydrochloric (HCl) oxidation using a mixed gas of an O₂ gas and an HCl gas, oxidation using a mixed gas of an O₂ gas and a trichloroethane (C₂H₃Cl₃) gas, or oxidation using a mixed gas of an O₂ gas and a dichloroethene (C₂H₂Cl₂) gas. In addition, the oxide layer (SiO₂) may be formed by a chemical vapor deposition (CVD) method.

The high-k material is formed of hafnia (HfO₂), zirconia (ZrO₂), aluminum oxide (Al₂O₃), tantalum oxide (Ta₂O₅), hafnium silicate, or zirconium silicate, or a combination thereof, by an atomic layer deposition (ALD) method. As the thickness of the tunneling insulating layer 34 decreases, a high-k material should be used. The tunneling insulating layer 34 has a thickness smaller than the gate insulating layer 20. In other words, the tunneling insulating layer 34 has a thickness of about 5 to about 100 angstrom (Å), preferably about 5 to about 50 angstroms (Å).

The upper floating gate 35 is formed on the first and second lower floating gates 32L and 32R and the tunneling insulating layer 34 and fills in a region between the first lower floating gate 32L and the second lower floating gate 32R. The upper floating gate 35 and the first and second lower floating gates 32L and 32R are electrically connected to each other and electric charges passing through the tunneling insulating layer 34 move to the first and second lower floating gates 32L and 32R through the upper floating gate 35.

The upper floating gate 35 is formed of a material that is the same as the material used for forming the first and second lower floating gates 32L and 32R. It is preferable that the total sum of thicknesses of the upper floating gate 35 and the first and second lower floating gates 32L and 32R be between about 1000 and about 2500 angstroms (Å).

The inter-gate insulating layer 37 is formed on the upper floating gate 35 and electrically insulates the first and second lower floating gates 32L and 32R, the upper floating gate 35, and the control line 38. The inter-gate insulating layer 37 may be formed of oxide nitride oxide (ONO)(SiO₂—Si₃N₄—SiO₂), silicon dioxide (SiO₂), silicon oxynitride (SiON), silicon nitride (Si₃N₄), germanium oxynitride (GeₓO_{y}N_{z}), germanium silicon oxide (GeₓSi_{y}O_{z}), or a high-k material. The inter-gate insulating layer 37 has a thickness of about 100 to about 300 angstoms (Å).

The control line 38 is formed on the inter-gate insulating layer 37 and may be a conducive polysilicon layer, a metal layer formed of tungsten (W), platinum (Pt), or aluminum (Al), a metal nitride layer formed of TiN, or a metal silicide layer formed of a refractory metal such as cobalt (Co), nickel (Ni), titanium (Ti), hafnium (Hf), or platinum (Pt), or a combination thereof. Alternatively, the control line 38 may be formed by sequentially depositing a conductive polysilicon layer and a metal silicide layer or a conductive polysilicon layer and a metal layer. The widely used conductive polysilicon layer is formed using dichlorosilane (SiH₂Cl₂) and a phosphine (PH₃) gas in a low pressure chemical vapor deposition (LPCVD) method.

Here, in the memory transistor 30, the lateral profiles of the first and second lower floating gates 32L and 32R, the upper floating gate 35, and the inter-gate insulating layer 37 are substantially the same as the lateral profile of the control line 38.

The select transistor 60 is separated from the memory transistor 30 by a predetermined interval on the active region 12 and has a stacked structure which includes a lower floating gate 62, an upper floating gate 65, an inter-gate insulating layer 67, and a word line 68. Moreover in this exemplary embodiment, the select transistor 60 is formed of a material that is the same material as used in forming the memory transistor 30 and has a configuration that is the same as that of the memory transistor 30 except for the tunneling insulating layer 34. In other words, the word line 68 is formed without forming the lower floating gate 62, the upper floating gate 65, and the inter-gate insulating layer 67. Alternatively, the lower floating gate 62 and the upper floating gate 65, and the word line 68 may be formed to have a predetermined step.

In the select transistor 60, the lateral profiles of the lower floating gate 62, the upper floating gate 65, and the inter-gate insulating layer 67 are substantially the same as the lateral profile of the word line 68.

A spacer 39 is formed at a side wall of the memory transistor 30 and a spacer 69 is formed at a side wall of the select transistor 60.

Three impurity regions 70, 80, and 90 are formed on the semiconductor substrate 10. The first impurity region 70 serves as a channel region, the second impurity region 80 serves as a common source region, and the third impurity region 90 serves as a drain region.

The first impurity region 70 is formed such that a portion of the first impurity region 70 overlaps with the word line 68 of the select transistor 60. The non-volatile memory device includes but is not limited to a first high-concentration impurity region 72 and a first low-concentration impurity region 74 formed adjacently to the first high-concentration impurity region 72. For example, the first high-concentration impurity region 72 is aligned in a region between the first lower floating gate 32L and the second lower floating gate 32R. By forming the first high-concentration impurity region 72 in this way, a sufficient margin in the distance between the first impurity region 70 and the second impurity region 80 is obtained. Thus, even when the size of the non-volatile memory cell is reduced, an effective channel length increases, thereby preventing a short channel effect from occurring and thus also preventing a drift current from occurring between the second impurity region 80 and the third impurity region 90. Accordingly, degradation of the device characteristic caused by a deviation of a threshold voltage (Vth) of a non-volatile memory device due to a drift current is prevented. Moreover, since the first impurity region 70 is formed under the tunneling window 22, misalignment between the first impurity region 70 and the tunneling window 22 is also prevented.

The second impurity region 80 is separated from the first impurity region 70 by a predetermined interval and it's portion overlaps with the memory transistor 30. The second impurity region 80 includes a second high-concentration impurity region 82 and a second low-concentration impurity region 84 formed adjacently to each other. In the second impurity region 80, the second high-concentration impurity region 82 and the second low-concentration impurity region 84 have lightly doped drain (LDD) structures. In this case, an effective channel length greater than in double diffused drain (DDD) structures is provided between the first impurity region 70 and the second impurity region 80.

The third impurity region 90 is separated from the first impurity region 70 by a predetermined interval and it's portion overlaps with the select transistor 60. The third impurity region 90 includes a third high-concentration impurity region 92 and a third low-concentration impurity region 94 that are adjacent to each other. In the third impurity region 90, the third high-concentration impurity region 92 has a DDD structure that is shallower than that of the third low-concentration impurity region 94.

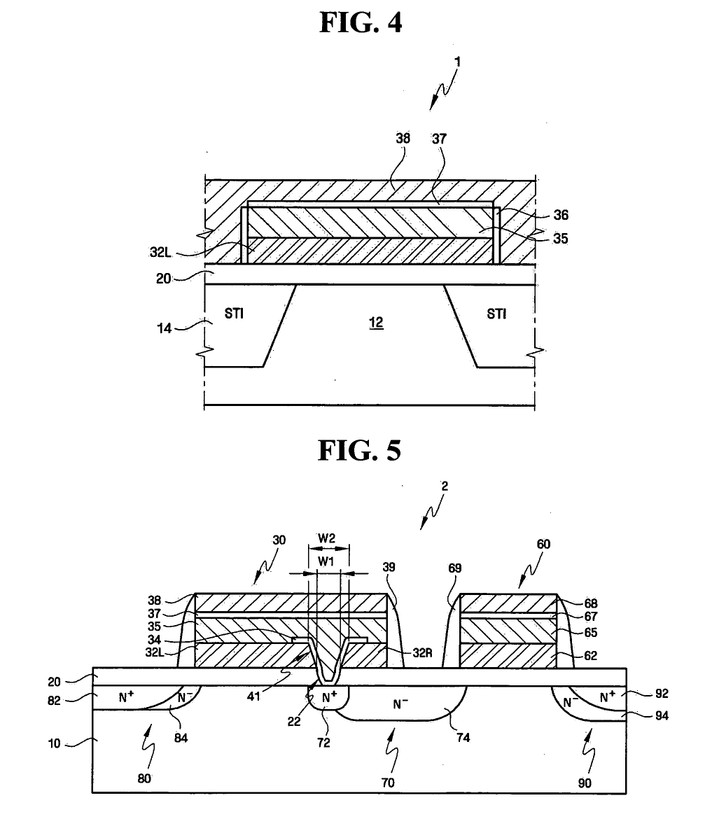

FIG. 5 is a sectional view of a non-volatile memory device according to an exemplary embodiment of the present invention.

Referring to FIG. 5, this exemplary embodiment of the present invention is substantially the same as the previous exemplary embodiment of FIGS. 1-4, except that the region between the first lower floating gate 32L and the second lower floating gate 32R has an inclined surface having a predetermined angle. In the description which follows, for the purposes of brevity, elements which are the same as, or similar to one another, will be identified using the same reference numerals, and a description thereof will not be given.

Referring back to the exemplary embodiment of FIG. 5, the region between the first lower floating gate 32L and the second lower floating gate 32R has an inclined surface having a predetermined angle. Thus, the interval W2 between the first lower floating gate 32L and the second lower floating gate 32R is greater than the width W1 of the tunneling window 22. The inclined surface is formed using a dry etching process and will be described in detail below.

Since the tunneling window 22 is formed along the inclined surface of the region between the first lower floating gate 32L and the second lower floating gate 32R, the tunnel window 22 is formed to a smaller width. In addition, since the first low-concentration impurity region 72 is formed in a smaller region than in the previous exemplary embodiment of FIGS. 1-4, a sufficiently effective channel length is provided, thereby improving reliability of the non-volatile memory device 3.

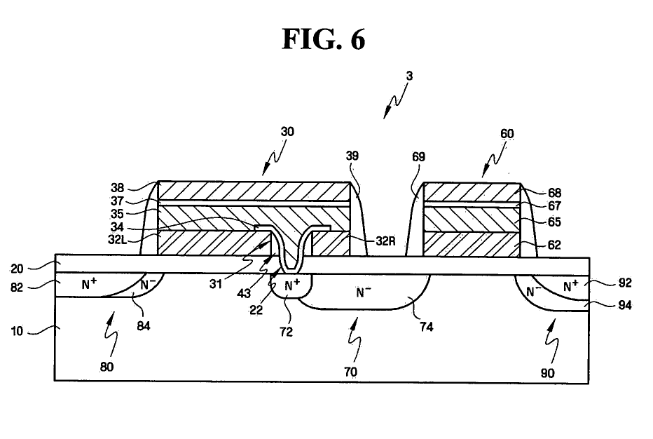

FIG. 6 is a sectional view of a non-volatile memory device according to an exemplary embodiment of the present invention. This exemplary embodiment of the present invention is substantially the same as the exemplary embodiment of FIGS. 1-4, except that a blocking insulating layer 43 is formed in a region between the first lower floating gate 32L and the second lower floating gate 32R. In the description which follows, elements which are the same as, or similar to one another, will be identified using the same reference numerals, and a description thereof will not be given.

Referring back to the exemplary embodiment of FIG. 6, the blocking insulating layer 43 is formed at side walls of the region between the first lower floating gate 32L and the second lower floating gate 32R and defines a contact area between the semiconductor substrate 10 and the upper floating gate 35. Moreover, the blocking insulating layer 43 is formed at side walls of a first opening 31 and takes the form of a spacer. The blocking insulating layer 43 is formed of a material having etching selectivity with respect to the gate insulating layer 20. For example, if the gate insulating layer 20 is an oxide layer, the blocking insulating layer 43 may be a nitride layer.

Since the tunneling window 22 is formed along the blocking insulating layer 43 in this exemplary embodiment of the present invention, the tunneling window 22 is formed to a smaller width. In addition, since the first high-concentration impurity region 72 is formed along the blocking insulating layer 43 in a smaller region than in the exemplary embodiment of FIGS. 1-4, a sufficiently effective channel length is provided, thereby further improving reliability of the non-volatile memory device 3.

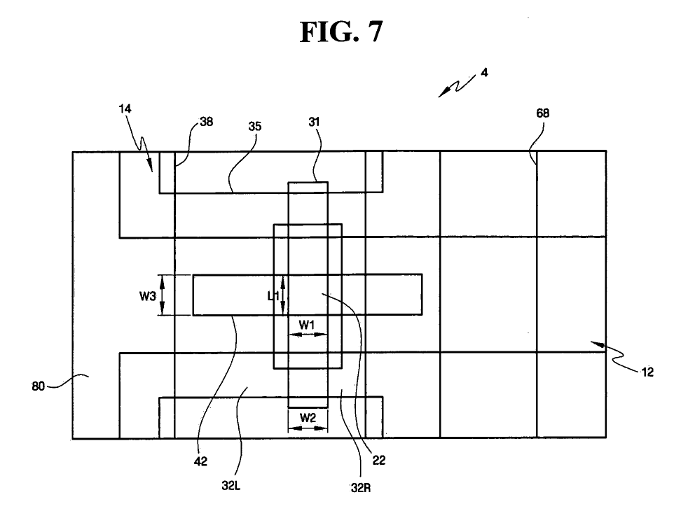

FIG. 7 is a layout view of a non-volatile memory device according to an exemplary embodiment of the present invention.

Referring to FIG. 7, this exemplary embodiment of the present invention is substantially the same as the exemplary embodiment of FIGS. 1-4, except that the plurality of memory cells that are adjacent to one another in a direction (i.e., the Y-axis direction of FIG. 1) perpendicular to a channel length direction (i.e., the X-axis direction of FIG. 1), are not collectively etched. Rather, each memory cell is etched individually during the first etching process of patterning a first conductive layer to separate the first conductive layer by an interval that is substantially the same as the width W1 of the tunneling window 22. In addition, the plurality of memory cells adjacent in the channel length direction (i.e., the X-axis direction of FIG. 1) are also not collectively etched during the second etching process. Instead, each memory cell is etched individually during the second etching process of patterning the first conductive layer using a photoresist pattern that exposes an interval that is substantially the same as the length L1 of the tunneling window 22. In the description which follows, elements which are the same as, or similar to one another, will be identified using the same reference numerals, and a description thereof will not be given.

In other words, the first opening 31 having the predetermined width W2 and a predetermined length L2 is formed in the first conductive layer during the first etching process and a photoresist pattern having a second opening 42 having a predetermined width W3 and a length L3 is formed during the second etching process, thereby forming the tunneling window 22 in a commonly etched region.

Further, in the embodiment shown in FIG. 7, once the first opening 31 formed during the first etching process is patterned in the channel length direction after a second conductive layer for forming an upper floating gate is formed on the first conductive layer, the shape of the first opening 31 is not maintained. In other words, the first lower floating gate 32L and the second lower floating gate 32R are separated from each other by a predetermined interval.

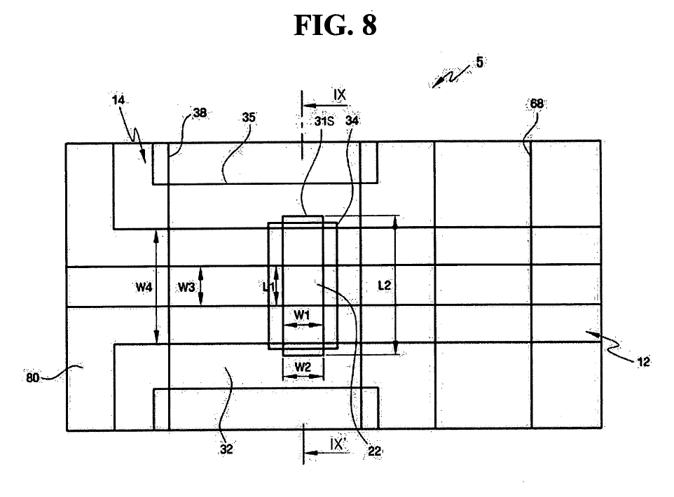

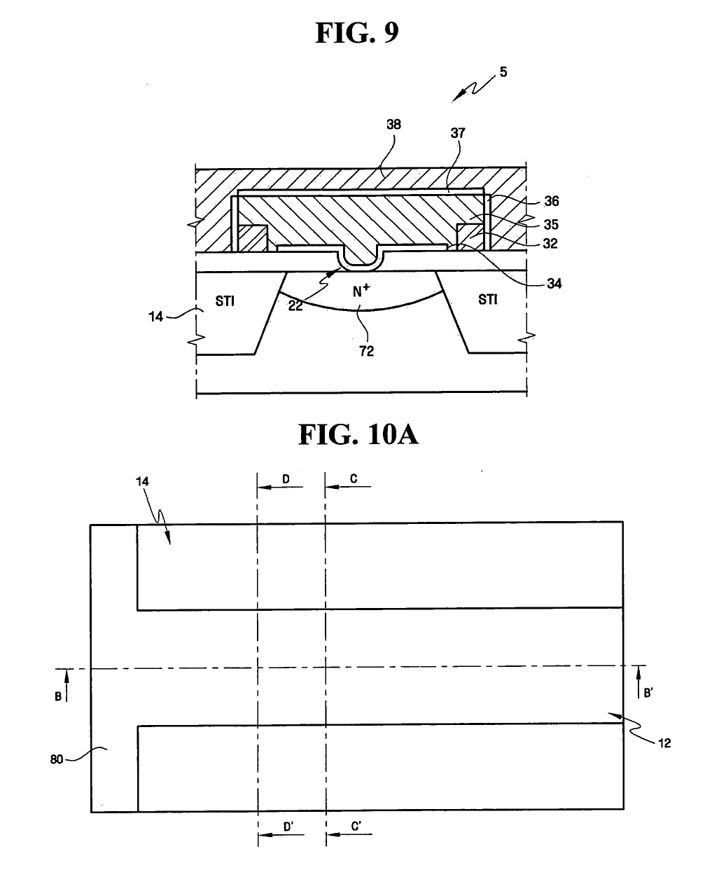

FIG. 8 is a layout view of a non-volatile memory device according to an exemplary embodiment of the present invention, and FIG. 9 is a sectional view of the non-volatile memory device, taken along a line IX-IX′ of FIG. 8.

Referring to FIGS. 8 and 9, the tunneling window 22 is formed by a first etching process of forming a first opening 31S in the first conductive layer and a second etching process of patterning the first conductive layer using a photoresist pattern that exposes the width W3 that is substantially the same as the length L1 of the tunneling window 22. In other words, the tunneling window 22 is formed in a region that is commonly patterned by the two etching processes.

In this exemplary embodiment of the present invention shown in FIG. 8, unlike in the exemplary embodiment shown in FIG. 7, the shape of the first opening 31S formed during the first etching process is maintained even when the first opening 31S is patterned in the channel length direction (i.e., the X-axis direction of FIG. 1) after a second conductive layer is formed on the first conductive layer.

Additionally, in the exemplary embodiment shown in FIG. 9, a lower floating gate 32 partially remains in both sides of the tunneling layer 34 even when the non-volatile memory device 5 of this exemplary embodiment is taken along a line IX-IX′. This is because the first conductive layer in the direction along IX-IX′ is not entirely etched when the first opening 31S is formed.

Further, during the second etching process, the plurality of memory cells that are adjacent to one another in the channel length direction X are etched, rather than being collectively etched, using a photoresist pattern having a second opening with a length greater than the width W1 of the tunneling window 22 as an etch mask.

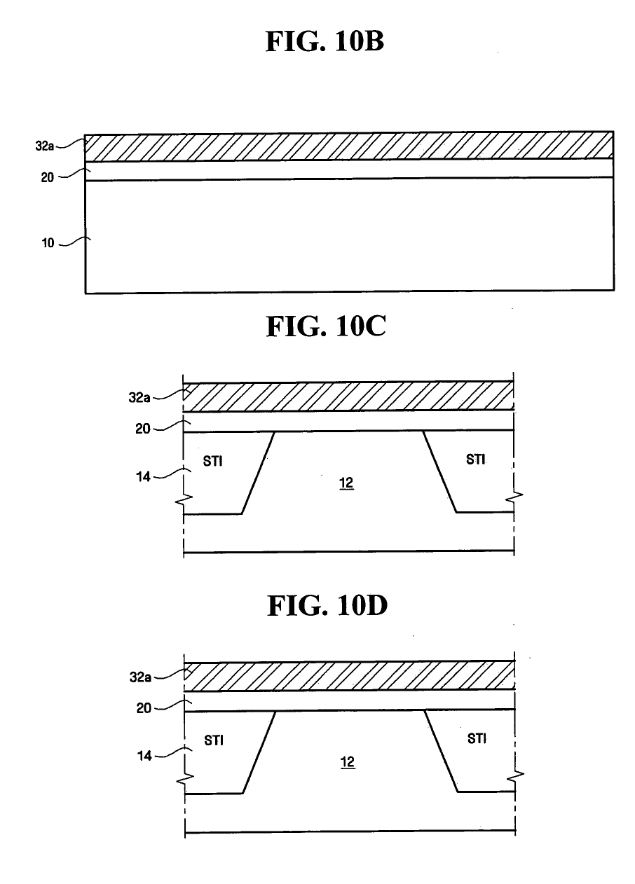

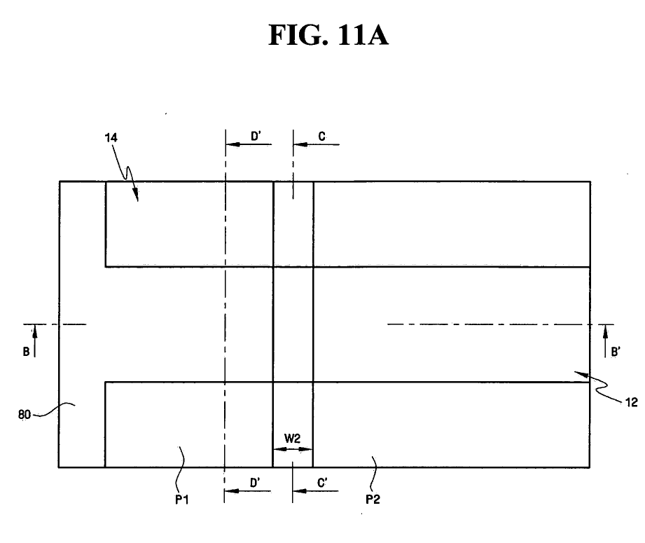

Hereinafter, a method of manufacturing the non-volatile memory device according to the exemplary embodiment of the present invention of FIGS. 1-4 will be described with reference to FIGS. 10A through 15D.

FIG. 10A is a layout view for illustrating a method of manufacturing the non-volatile memory device shown in FIG. 1 and FIGS. 10B through 10D are sectional views of the non-volatile memory device, taken along lines B-B′, C-C′, and D-D′ of FIG. 10A.

Referring to FIGS. 10A through 10D, the active region 12 and the device isolation region 14 are defined in the semiconductor substrate 10. The device isolation device 14 of the non-volatile memory device 1 according to the exemplary embodiment of FIGS. 1-4 may be in a Shallow Trench Isolation (STI) structure.

Next, the gate insulating layer 20 is formed on the semiconductor substrate 10. The gate insulating layer 20 is formed on the semiconductor substrate 10. The gate insulating layer 20 is formed of silicon dioxide (SiO₂), silicon oxynitride (SiON), silicon nitride (Si₃N₄), germanium oxynitride (GeₓO_{y}N_{z}), germanium silicon oxide (GexSi_{y}O_{z}), a high dielectric constant (k) material, or a combination thereof. Here, the high-k material is formed of hafnia (HfO₂), zirconia (ZrO₂), aluminum oxide (Al₂O₃), tantalum oxide (Ta₂O₅), hafnium silicate, zirconium silicate, or a combination thereof, by an atomic layer deposition (ALD) method. The gate insulating layer 20 preferably has a thickness of about 200 to about 500 angstroms (Å).

A first conductive layer 32a is formed on the gate insulating layer 20. The first conductive layer 32a is formed by a chemical vapor deposition (CVD) method or an atomic layer deposition (ALD) method. The first conductive layer 32a is formed of n+ polysilicon, p+ polysilicon, silicon germanium (SiGe), or a metallic material.

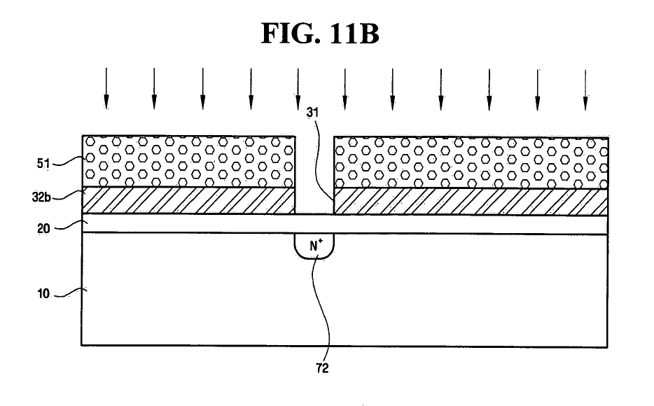

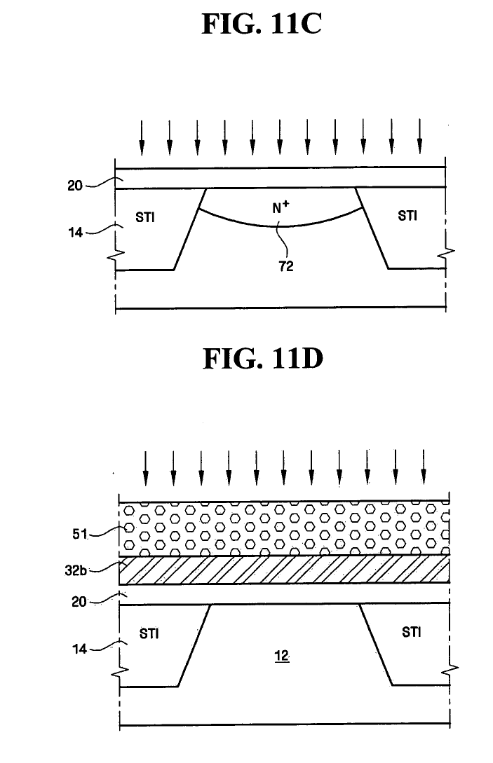

FIG. 11A is a layout view for illustrating a method of manufacturing the non-volatile memory device shown in FIG. 1, and FIGS. 11B through 11D are sectional views of the non-volatile memory device, taken along lines B-B′, C-C′, and D-D′ of FIG. 11A.

Referring to FIGS. 11A through 11D, a first photoresist pattern 51 is formed on the first conductive layer 32a. A first-conductive-layer pattern 32b is formed by patterning the first conductive layer 32a using the first photoresist pattern 51 as an etching mask such that the first-conductive-layer pattern 32b is separated from the first conductive layer 32a by the interval W2 that is substantially the same as the width W1 of the tunneling window 22 to be formed in the gate insulating layer 20. In other words, the first-conductive-layer pattern 32b includes a first-conductive-layer first pattern p1 and a first-conductive-layer second pattern p2 separated by a predetermined interval wherein a region in which the tunneling window 22 is to be formed and a portion of a gate insulating layer around the region are exposed. It is preferable that the first-conductive-layer pattern 32b be formed by an anisotropic dry etching process.

Next, a first high-concentration impurity region 72 for a channel region is formed by implanting high-concentration impurities in the semiconductor substrate 10 using the first photoresist pattern 51 and the first-conductive-layer pattern 32b as an ion-implanting mask. The first high-concentration impurity region 72 is formed by implanting impurities of a type that is opposite to that of the semiconductor substrate 10 at a dose of about 1.0×10¹³ to about 1.0×10¹⁴ atoms/cm² with an implanting energy of about 40 to about 200 keV. For example, when the impurities are phosphorus (P+) impurities, they are implanted with an implanting energy of about 40 to about 100 keV, and when the impurities are arsenic (As+), they are implanted with an implanting energy of about 100 to about 200 keV.

When ion implantation is performed on the first-conductive-layer pattern 32b, the first photoresist pattern 51 is removed after the formation of the first-conductive-layer pattern 32b and ion implantation is performed using the first-conductive-layer pattern 32b as an ion-implanting mask.

As described above, if the first high-concentration impurity region 72 is formed using the first photoresist pattern 51 and the first-conductive-layer pattern 32b as ion-implanting masks, a sufficient margin in the distance between the first high-concentration impurity region 72 and a potential region of the second impurity region (80 of FIG. 2) is obtained. Thus, even when the size of a non-volatile memory cell is reduced, the effective channel length increases, thereby preventing a short channel effect from occurring. Accordingly, occurrence of a drift current between the second impurity region 80 and the third impurity region (90 of FIG. 2) is avoided. Thus, a drift current is prevented from increasing between the second impurity region 80 and the third impurity region 90, thereby also preventing an increase in the deviation of the threshold voltage (Vth) of the non-volatile memory device. Moreover, since the first impurity region 70 is formed under the tunneling window 22, misalignment between the first impurity region 70 and the tunneling window 22 is also prevented.

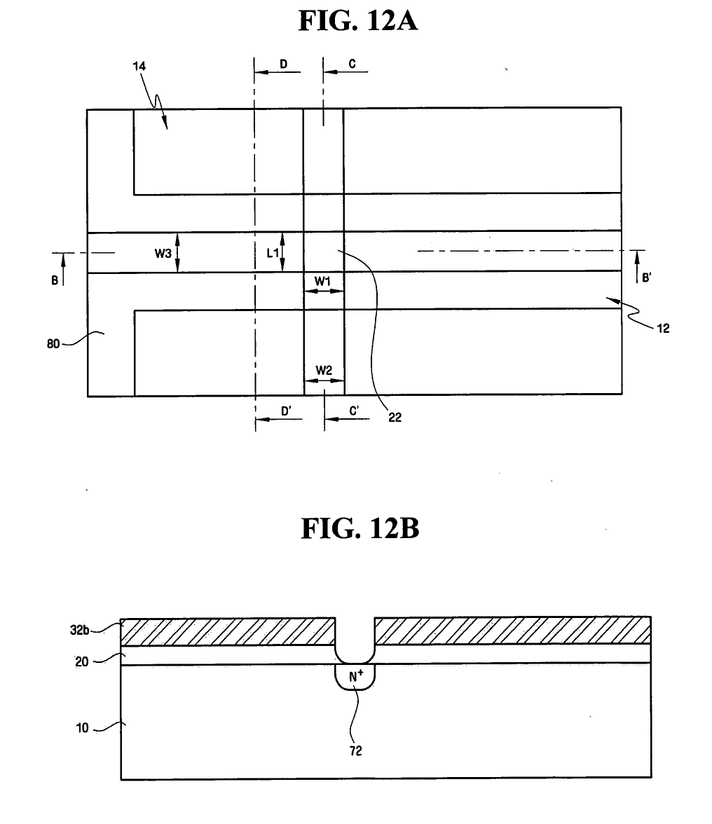

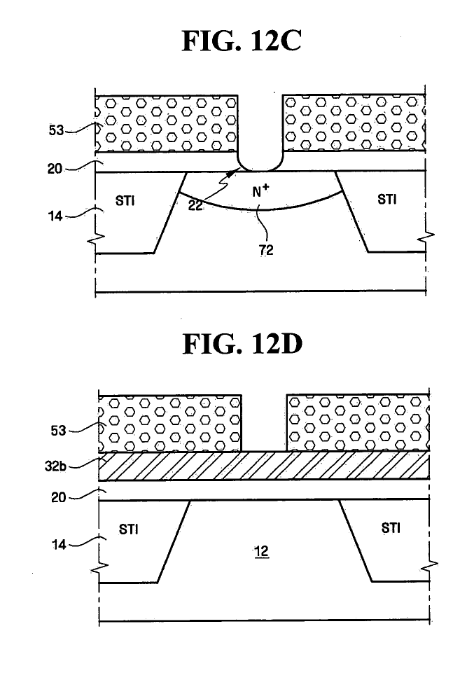

FIG. 12A is a layout view for illustrating a method of manufacturing the non-volatile memory device shown in FIG. 1, and FIGS. 12B through 12D are sectional views of the non-volatile memory device, taken along lines B-B′, C-C′, and D-D′ of FIG. 12A.

Referring to FIGS. 12A through 12D, a second photoresist layer is coated on the first-conductive-layer pattern 32b and is then patterned, thereby forming a second photoresist pattern 53. The second photoresist pattern 53 is patterned by the interval W3 that is substantially the same as the length L1 of the tunneling window 22 to be formed in the gate insulating layer 20.

The tunneling window 22 is formed by etching a portion of the gate insulating layer 20 using the second photoresist pattern 53 as an etching mask. Here, etching is performed such that the first-conductive-layer pattern 32b is not etched, but the gate insulating layer 20 exposed by the first-conductive-layer pattern 32b is only selectively removed. For example, a combination of wet etching and dry etching or wet etching may be used.

The tunneling window 22 of the non-volatile memory device 1 according to the exemplary embodiment of FIG. 1 is formed by a first etching process and a second etching process. In the first etching process, a first conductive layer is patterned such that the first conductive layer is separated by a predetermined interval, e.g., the interval W2 that is substantially the same as the width W1 of the tunneling window 22. In the second etching process, the first conductive layer is patterned using a photoresist pattern that exposes the interval W3 that is substantially the same as the length L1 of the tunneling window 22. In other words, the tunneling window 22 is stably formed in a region that is commonly etched by each of the two etching processes, thereby reducing the width of tunneling window 22 to about 0.14 μm or less.

Although the exemplary embodiment of FIG. 1 has shown that the plurality of memory cells adjacent to one another in the channel length direction (i.e., the X-axis direction FIG. 1) are collectively etched, the plurality of memory cells may alternatively be etched individually as shown in FIG. 7. In other words, after a photoresist pattern including an opening is formed on the gate insulating layer 20 and the first-conductive-layer pattern 32b with a length greater than the width of the tunneling window 22 to be formed in the gate insulating layer 20, a portion of the gate insulating layer 20 is etched using the photoresist pattern as an etching mask to then complete the formation of the tunneling window 22.

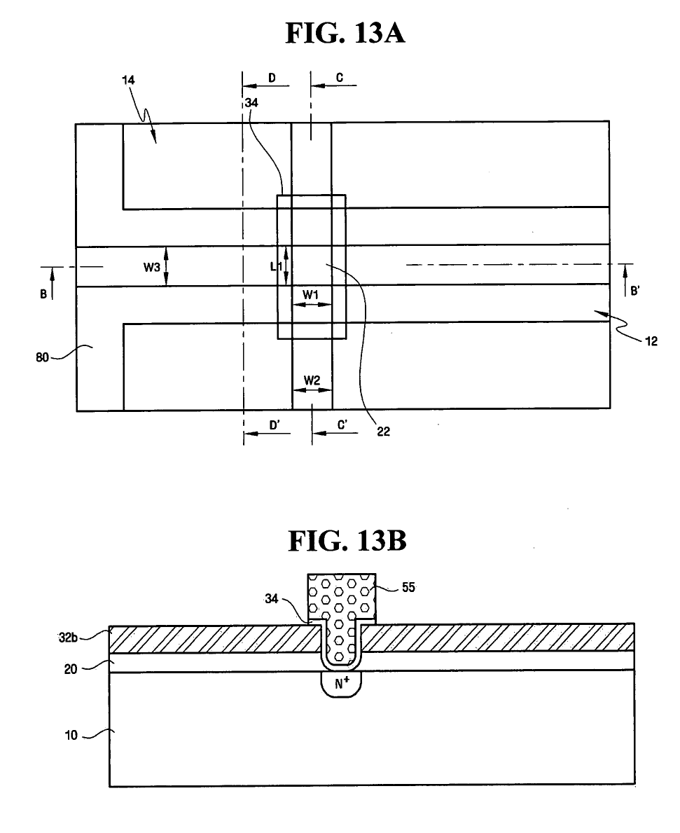

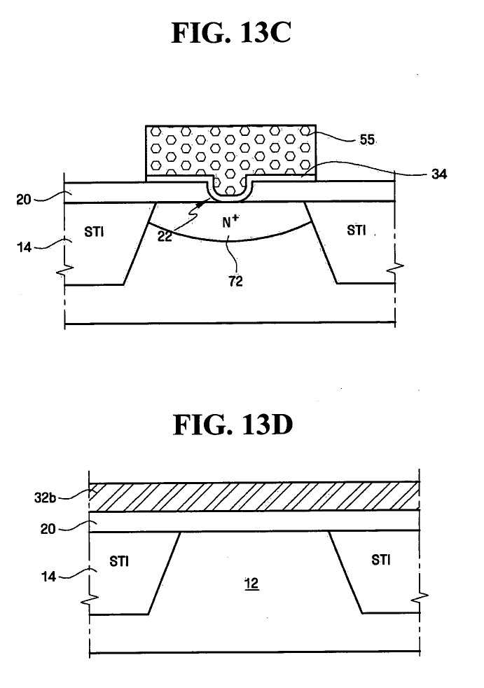

FIG. 13A is a layout view for illustrating a method of manufacturing the non-volatile memory device shown in FIG. 1, and FIGS. 13B through 13D are sectional views of the non-volatile memory device, taken along lines B-B′, C-C′, and D-D′ of FIG. 13A.

Referring to FIGS. 13A through 13D, an insulating layer is formed on the first-conductive-layer pattern 32b. First, the insulating layer is formed by growing a desired film from the surface of the first-conductive-layer pattern 32b through dry oxidation, wet oxidation, hydrochloric (HCl) oxidation, or oxidation using a mixed gas. Alternatively, chemical vapor deposition (CVD) or atomic layer deposition (ALD) may be used. The insulating layer is formed of a material that is the same material as that used in forming the gate insulating layer 20.

A third photoresist layer is formed on the insulating layer and is patterned to form a third photoresist pattern 55. The tunneling insulating layer 34 is formed by etching a portion of the insulating layer using the third photoresist pattern 55 as an etching mask. The tunneling insulating layer 34 has a thickness smaller than the gate insulating layer 20. In other words, the tunneling insulating layer 34 has a thickness of about 5 to about 100 Å, preferably about 5 to about 50 Å.

The tunneling insulating layer 34 is formed along profiles of the tunneling window 22 and the first-conductive-layer pattern 32b. Here, it is preferable that the tunneling insulating layer 34 cover as small a portion of the first-conductive-layer pattern 32b as possible to improve electric characteristics.

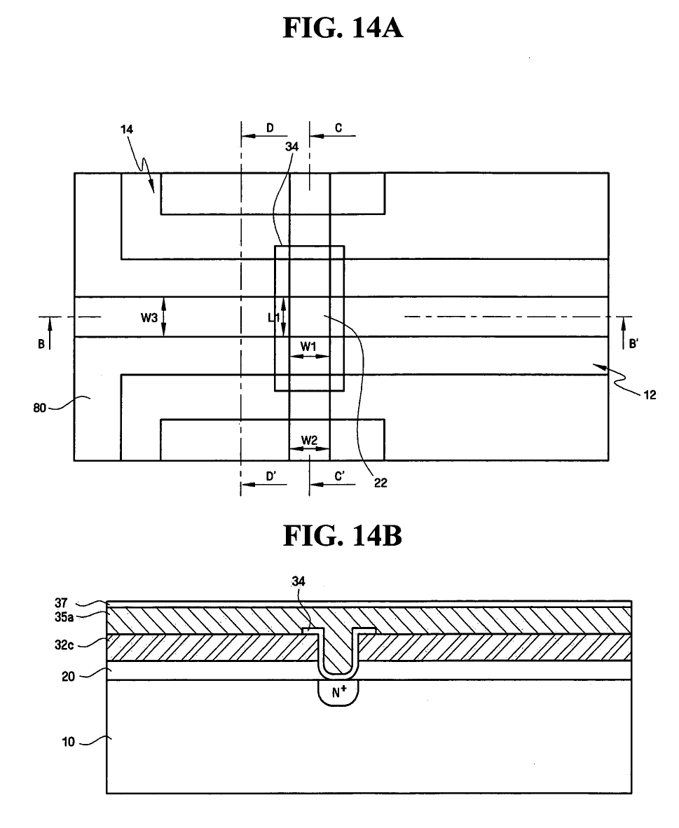

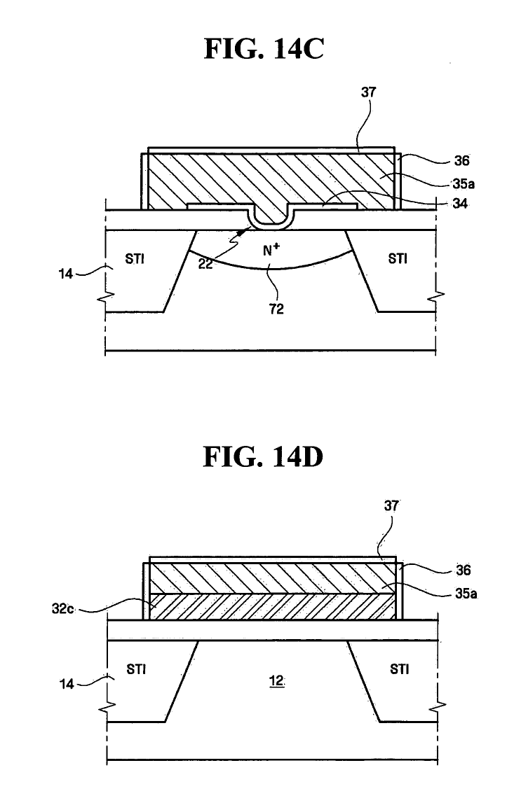

FIG. 14A is a layout view for illustrating a method of manufacturing the non-volatile memory device shown in FIG. 1, and FIGS. 14B through 14D are sectional views of the non-volatile memory device, taken along lines B-B′, C-C′, and D-D′ of FIG. 14A.

Referring to FIGS. 14A through 14D, a second conductive layer is formed on the tunneling layer 34 and the first-conductive-layer pattern 32b. The second conductive layer is formed by a CVD or ALD method, like those used to form the first conductive layer 32a. The second conductive layer is formed of n+ polysilicon, p+ polysilicon, SiGe, or a metallic material. It is preferable that the total sum of thicknesses of the first conductive layer 32a and the second conductive layer be between about 1000 and about 2500 angstroms (Å).

The inter-gate insulating layer 37 is formed on the second conductive layer. The inter-gate insulating layer 37 may be formed of silicon dioxide (SiO₂), silicon oxynitride (SiON), silicon nitride (Si₃N₄), germanium oxynitride (GeₓO_{y}N_{z}), germanium silicon oxide (GeₓSi_{y}O_{z}), or a high-k material. The inter-gate insulating layer 37 has a thickness of about 100 to about 300 angstroms (Å).

The first-conductive-layer pattern 32b, the second conductive layer, and the inter-gate insulating layer 37 are patterned in the channel length direction. A sidewall insulating layer 36 is formed by oxidating a first-conductive-layer pattern 32c and a second-conductive-layer pattern 35a. The sidewall insulating layer 36 has a thickness of about 300 angstroms (Å). Oxidation for forming the sidewall insulating layer 36 is performed simultaneously with oxidation in a logic/peripheral region.

If oxidation is not performed in a logic/peripheral region, the first-conductive-layer pattern 32b and the second conductive layer are patterned in the channel length direction and the inter-gate insulating layer 37 is formed on a resultant structure.

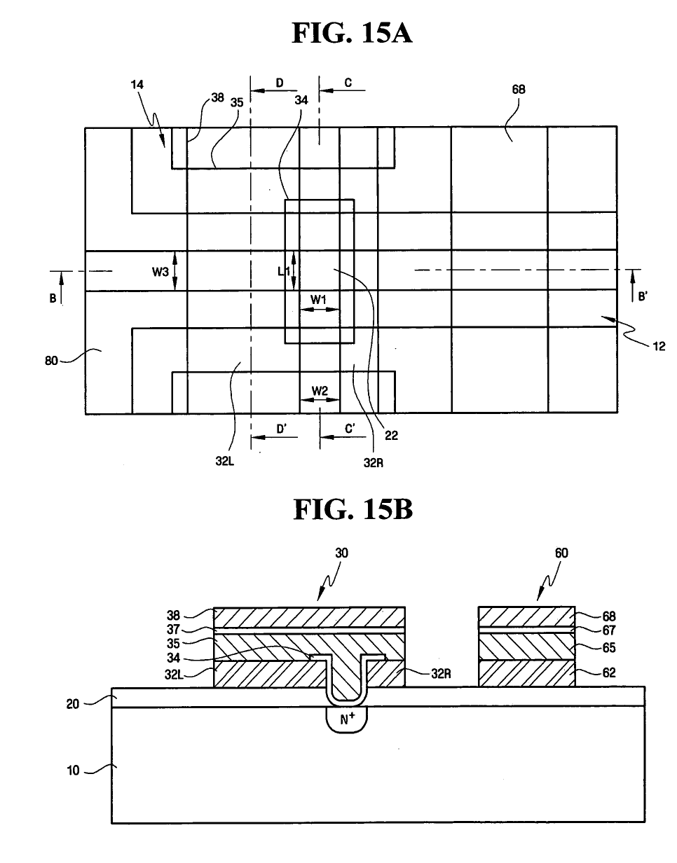

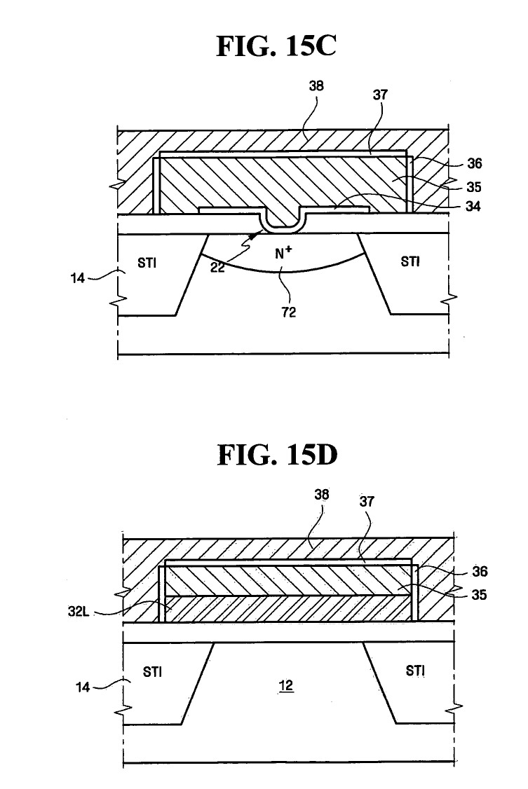

FIG. 15A is a layout view for illustrating a method of manufacturing the non-volatile memory device shown in FIG. 1, and FIGS. 15B through 15D are sectional views of the non-volatile memory device, taken along lines B-B′, C-C′, and D-D′ of FIG. 15A.

Referring to FIGS. 15A through 15D, a third insulating layer is formed on the inter-gate insulating layer 37. The third insulating layer is a conductive polysilicon layer, a metal layer formed of tungsten (W), platinum (Pt), or aluminum (Al), a metal nitride layer formed of titanium nitride (TiN), or a metal silicide layer formed of a refractory metal such as colbalt (Co), nickel (Ni), titanium (Ti), hafnium (Hf), or platinum (Pt), or a combination thereof. Alternatively, the third insulating layer may be formed by sequentially depositing a conductive polysilicon layer and a metal silicide layer or a conductive polysilicon layer and a metal layer. The widely used conductive polysilicon layer is formed using dichlorosilane (SiH₂Cl₂) and a phosphine (PH₃) gas by a low pressure chemical vapor deposition (LPCVD) method.

The first-conductive-layer pattern 32c, the second-conductive-layer pattern 35a, and the third conductive layer are patterned in a direction perpendicular to the channel length direction, thereby forming the memory transistor 30 and the select transistor 60. In other words, the control line 38, the word line 68, the upper floating gates 35 and 65, and the lower floating gates 32L, 32R, and 62 are formed.

Next, the first through third impurity regions 70-90 shown in FIGS. 1 through 4 are formed to then complete the formation of the non-volatile memory device 1 shown in FIGS. 1 through 4. The first low-concentration impurity region 74 of the first impurity region 70 and the third low-concentration impurity region 94 of the third impurity region 90 are formed by implanting low-concentration impurities in the semiconductor substrate 10 where the memory transistor 30 and the select transistor 60 are formed, using an ion-implanting mask that masks the second impurity region 70. Here, the first impurity region 70 serves as a channel region and the third impurity region 90 serves as a drain region.

Here, ion-implantation is performed such that phosphorus ions are implanted at a dose of about 1.0×10¹² to about 5.0×10¹³ atoms/cm² with an implanting energy of about 80 to about 90 keV. The first low-concentration impurity region 74 and the third low-concentration impurity region 94 formed under such implantation conditions are referred to as high-breakdown voltage N-type (HVN-) regions.

The second low-concentration impurity region 84 of the second impurity region 80 is formed by implanting low-concentration impurities in the semiconductor substrate 10 using an ion-implanting mask that masks the first impurity region 70 and the third impurity region 90 such that the second low-concentration impurity region 84 is spaced a predetermined interval apart from the first impurity region 70 and is aligned at a sidewall of the memory transistor 30.

Here, ion-implantation is performed such that phosphorus ions or arsenic ions are implanted at a dose of about 1.0×10¹² to about 5.0×10¹³ atoms/cm² with an implanting energy of about 30 to about 80 keV. The second low-concentration impurity region 84 formed under such implantation conditions, is referred to as a low-breakdown voltage N-type (LVN-) region.

After a spacer insulating layer is deposited over the entire surface of the semiconductor substrate 10 and is etched back, spacers 39 and 69 are formed at sidewalls of the memory transistor 30 and the select transistor 60.

The second high-concentration impurity region 82 of the second impurity region 80 and the third high-concentration impurity region 92 of the third impurity region 90 are formed by implanting high impurities in the semiconductor substrate 10 using an ion-implanting mask that masks the first impurity region 70.

Here, ion-implantation is performed such that arsenic ions are implanted at a dose of about 1.0×10¹⁵ to about 5.0×10¹⁵ atoms/cm² with an implanting energy of about 40 to about 60 keV.

Once the first through third impurity regions 70 through 90 are formed, the second impurity region 80 has a lightly doped drain (LDD) structure and the third impurity region 90 has a double diffused drain (DDD) structure.

The process of completing the final product after packaging in which the non-volatile memory device is routed may be accomplished in any of the various ways known to those skilled in the art.

Further, as discussed above, the method of manufacturing the non-volatile memory device 2 according to the exemplary embodiment of FIG. 5 is similar to the exemplary embodiment of FIGS. 1-4, except that the exemplary embodiment of FIG. 5 further includes inclined surface dry etching. In the embodiment of FIG. 5, the interval W2 between the first-conductive-layer first pattern p1 and the first-conductive-layer second pattern p2 is greater than the width of the tunneling window (22 of FIG. 1) to be formed in the gate insulating layer 20. Moreover, the inclined surface dry etching of the exemplary embodiment of FIG. 5 is performed using the following gases including but not limited to hydrogen bromide (HBr), chlorine (Cl), or heliox (HeO₂)(O₂) gases and the angle of inclination is controlled by changing the process condition of dry etching. The subsequent processes are performed in a similar manner to those performed in the exemplary embodiment of FIGS. 1-4.

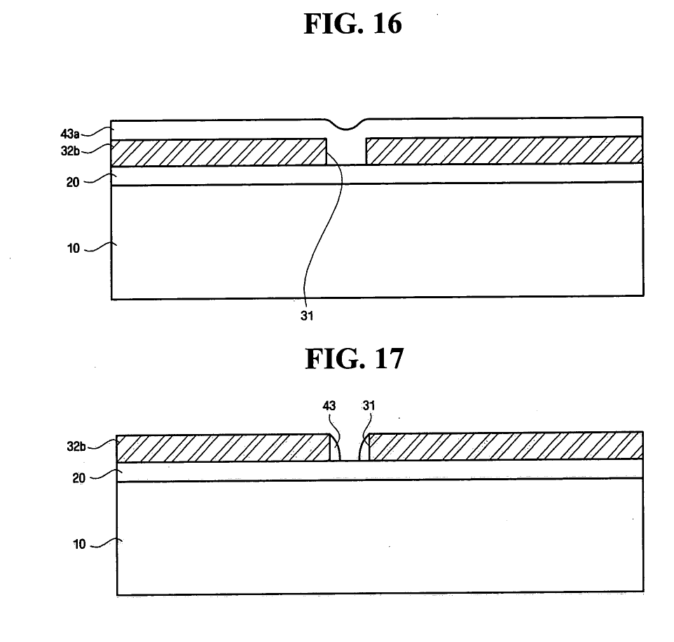

Additionally, as discussed above, the method of manufacturing the non-volatile memory device 3 according to the exemplary embodiment of FIG. 6 is similar to the exemplary embodiment of FIGS. 1-4 except that the exemplary embodiment of FIG. 6 further includes the formation of a blocking insulating layer. In other words, after the first-conductive-layer pattern 32b is formed in FIGS. 11A through 11D, an insulating material layer 43a is coated over the entire surface of the first-conductive-layer pattern 32b as shown in FIG. 16. Once the insulating material layer 43a is etched back as shown in FIG. 17, the blocking insulating layer 43 is formed at sidewalls of a region between the first-conductive-layer first pattern p1 and the first-conductive-layer second pattern p2. Due to the blocking insulating layer 43, the interval W2 between the first-conductive-layer first pattern p1 and the first-conductive-layer second pattern p2 becomes larger than the width of the tunneling window (22 of FIG. 1) to be formed in the gate insulating layer 20. The blocking insulating layer 43 is formed of a material having etching selectivity with respect to the gate insulating layer 20. For example, when the gate insulating layer 20 is an oxide layer, the blocking insulating layer 43 may be a nitride layer.

In addition, since the tunneling window 22 is formed along the blocking insulating layer 43 according to the exemplary embodiment of FIG. 6, the tunneling window 22 has a relatively small width. Further, since, in this exemplary embodiment, the first high-concentration impurity region 72 is formed in a smaller region than in the exemplary embodiment of FIGS. 1-4, a sufficiently effective channel length is provided, thereby improving the reliability of the non-volatile memory device 3. The subsequent processes in this embodiment are performed in a similar manner to those in the exemplary embodiment of FIGS. 1-4.

Also, as discussed above, the method of manufacturing the non-volatile memory device 4 according to the exemplary embodiment of FIG. 7 includes etching a plurality of memory cells that are adjacent to one another in a direction (i.e., the Y-axis direction of FIG. 1) perpendicular to the channel length direction for each memory cell during the first etching process in FIGS. 11A through 11D, instead of collectively etching the plurality of memory cells. In addition, during the second etching process in FIGS. 12A through 12D, the plurality of memory cells that are adjacent to one another in the channel length direction (i.e., the X-axis direction of FIG. 1) are etched for each memory cell, instead of being collectively etched. Moreover, the subsequent processes in this embodiment are performed in a similar manner to those in the exemplary embodiment of FIGS. 1-4.

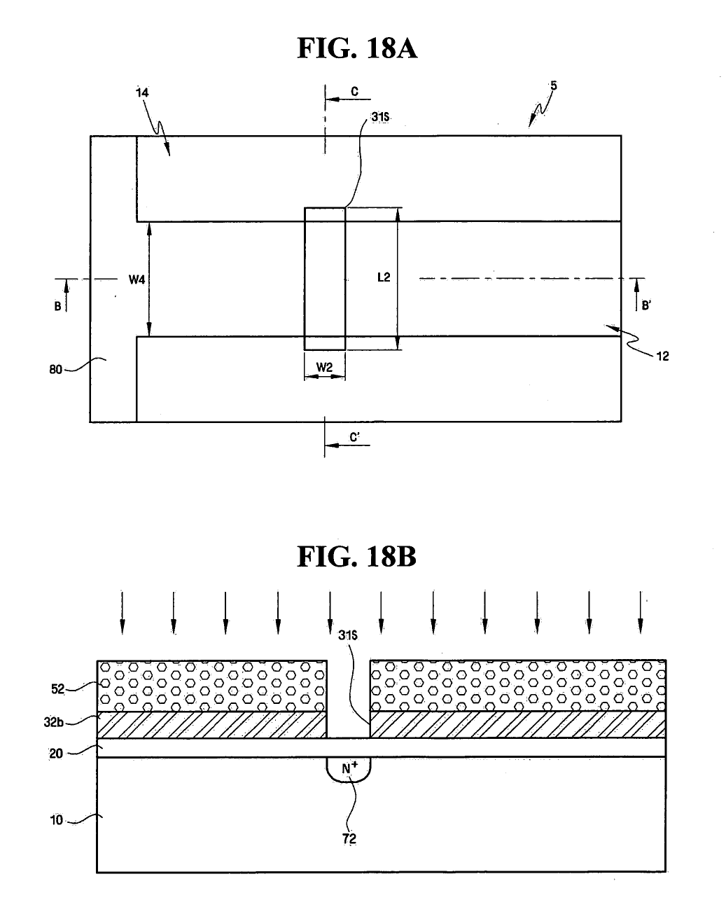

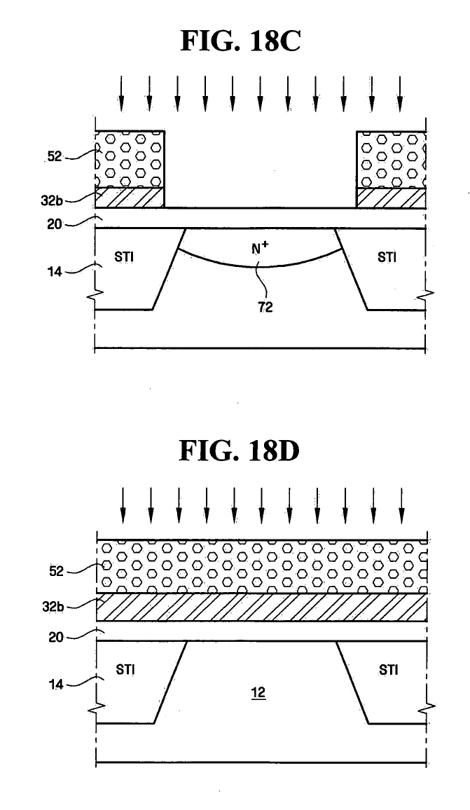

In a method of manufacturing the non-volatile memory device 5 according to an exemplary embodiment of the present invention, processes shown in FIGS. 18A through 20D, instead of the processes shown in FIGS. 11A through 13D, are performed.

FIG. 18A is a layout view for illustrating a method of manufacturing the non-volatile memory device shown in FIG. 8, and FIGS. 18B through 18D are sectional views of the non-volatile memory device, taken along lines B-B′, C-C′, and D-D′ of FIG. 18A.

Referring to FIGS. 18A through 18D, the first photoresist pattern 52 is formed on the first conductive layer 32a. The first-conductive-layer pattern 32b is formed using the first photoresist pattern 52 as an etching mask. Moreover, the first-conductive-layer pattern 32b is formed having a length L2 greater than the length of the tunneling window (22 of FIG. 1) to be formed in the gate insulating layer 20 and having a first opening 31 that partially exposes the tunneling window 22 and the gate insulating layer 20 that are adjacent to each other. It is preferable that the process for forming the first opening 31 using the first photoresist pattern 52 be performed using an anisotropic dry etching technique.

In particular, it is preferable that the length L2 of the first opening 31 be greater than a width W4 of an active region of the semiconductor substrate 10. In addition, it is preferable that the width W2 of the first opening 31 be substantially the same as the width W1 of the tunneling window 22 to be formed in the gate insulating layer 20.

The first high-concentration impurity region 72 for the channel region is formed by implanting high-concentration impurities in the semiconductor substrate 10 using the first photoresist pattern 52 and the first-conductive-layer pattern 32b as ion-implanting masks.

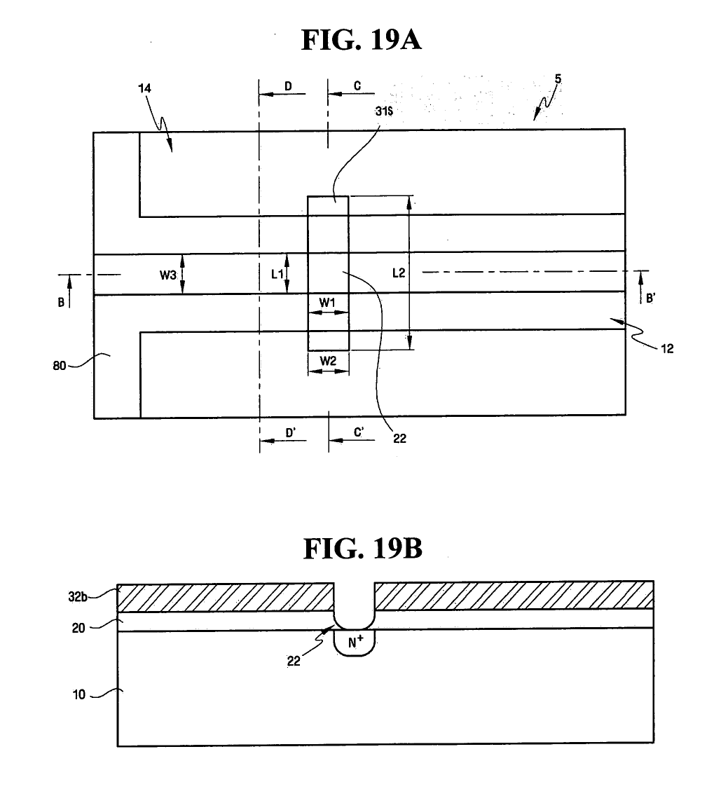

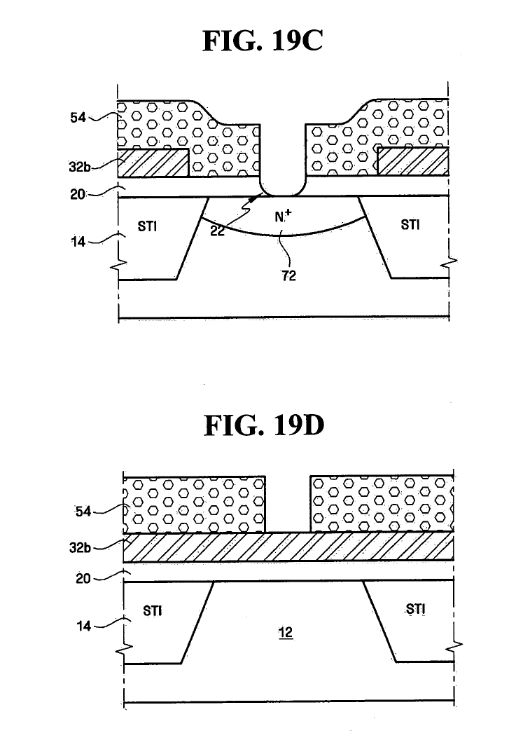

FIG. 19A is a layout view for illustrating a method of manufacturing the non-volatile memory device shown in FIG. 8, and FIGS. 19B through 19D are sectional views of the non-volatile memory device, taken along lines B-B′, C-C′, and D-D′ of FIG. 19A.

Referring to FIGS. 19A through 19D, the second photoresist layer is coated over the first-conductive-layer pattern 32b and is patterned, thereby forming the second photoresist pattern 54 patterned by the interval W3 that is substantially the same as the length L1 of the tunneling window 22 to be formed in the gate insulating layer 20. The tunneling window 22 is formed by etching a portion of the gate insulating layer 20 using the second photoresist pattern 54 as an etching mask.

Although in this exemplary embodiment the plurality of memory cells that are adjacent to one another in the channel length direction (i.e., the X-axis direction of FIG. 1) are collectively etched, the plurality of memory may alternatively be etched individually as in FIG. 7. In other words, after a photoresist pattern having a second opening is formed on the gate insulating layer and the first-conductive-layer pattern 32b with a length greater than the width of the tunneling window to be formed in the gate insulating layer, a portion of the gate insulating layer 20 is then etched using the photoresist pattern as an etching mask, thereby forming the tunneling window.

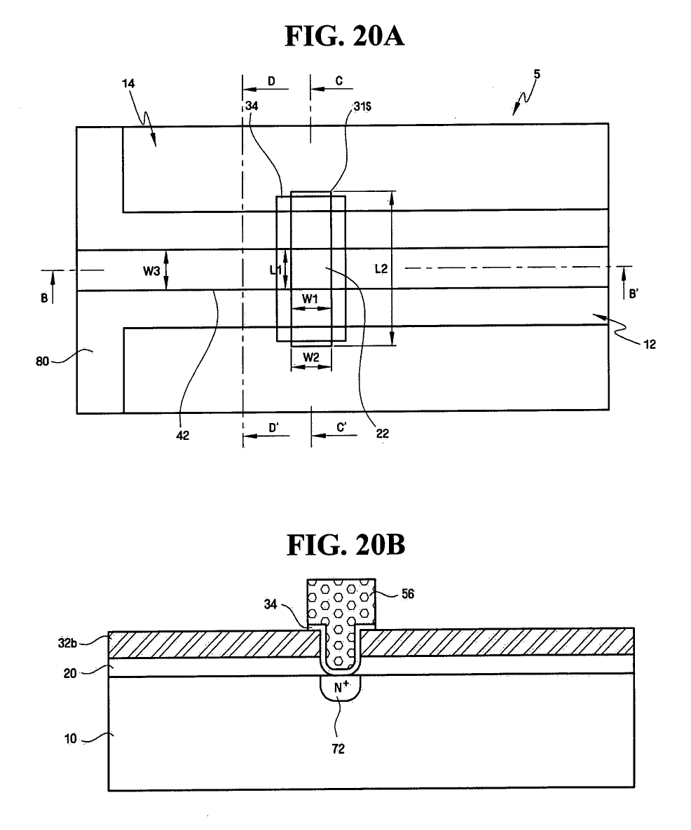

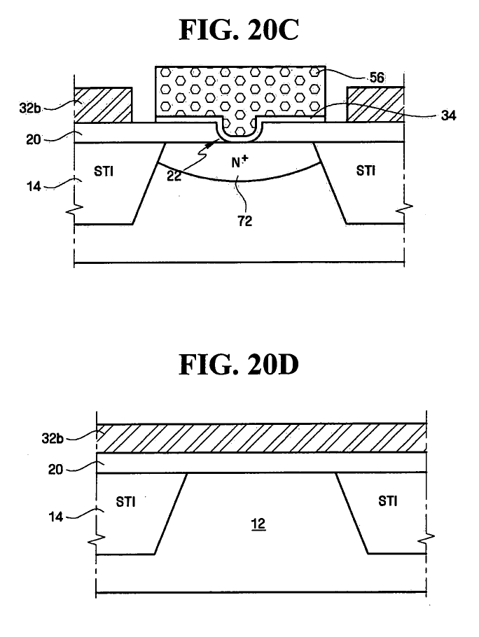

FIG. 20A is a layout view for illustrating a method of manufacturing the non-volatile memory device shown in FIG. 8, and FIGS. 20B through 20D are sectional views of the non-volatile memory device, taken along lines B-B′, C-C′, and D-D′ of FIG. 20A.

Referring to FIGS. 20A through 20D, an insulating layer is formed on the first-conductive-layer pattern 32b. A third photoresist layer is formed on the insulating layer and is patterned, thereby forming a third photoresist pattern 56. A portion of the insulating layer is etched using the photoresist pattern 56 as an etching mask, thereby forming the tunneling insulating layer 34. The subsequent processes are performed in a similar manner to those performed in the exemplary embodiment of FIGS. 1-4.

The non-volatile memory device and method of manufacturing the same according to the exemplary embodiments of the present invention provide at least the following of: improved operating characteristics of the non-volatile memory cell by increasing the coupling ratio through reducing an area of a tunneling window,

the prevention of a short channel effect in the non-volatile memory cell since a sufficient margin in the distance between a common source region and a channel region is obtained,

the prevention of the deviation of the threshold voltage of the non-volatile memory cell from increasing by preventing a drift current from occurring between the common source region and the channel region, and

the prevention of misalignment from occurring between the channel region and the tunneling window.

Having described the exemplary embodiments, it is further noted that it is readily apparent to those of ordinary skill in the art that various modifications may be made without departing from the spirit and scope of the present invention as defined by the metes and bounds of the appended claims.

What is claimed is:

1. A non-volatile memory device comprising:
a gate insulating layer having a tunneling window formed therein, said tunneling window having a predetermined width parallel to a channel length direction and having a predetermined length perpendicular to the channel length direction on a semiconductor substrate;
a lower floating gate comprising a first lower floating gate formed on the gate insulating layer and a second lower floating gate spaced a predetermined interval apart from the first lower floating gate, wherein the tunneling window and a portion of the gate insulating layer which is adjacent to the tunneling window are partially exposed in a region between the first lower floating gate and the second lower floating gate;
a tunneling insulating layer formed on the tunneling window;
an upper floating gate which is formed on the lower floating gate and the tunneling insulating layer and fills the region between the first lower floating gate and the second lower floating gate;
an inter-gate insulating layer formed on the upper floating gate; and
a memory transistor having a control line formed on the gate insulating layer.

2. The non-volatile memory device of claim 1, wherein the predetermined interval is substantially the same as a width of the tunneling window.

3. The non-volatile memory device of claim 1, wherein the predetermined interval is greater than a width of the tunneling window, and wherein the region between the first lower floating gate and the second lower floating gate has an inclined surface with a predetermined angle.

4. The non-volatile memory device of claim 1, further comprising a blocking insulating layer which is formed at sidewalls of the region between the first lower floating gate and the second lower floating gate and defines a contact area between the semiconductor substrate and the lower floating gate, wherein the predetermined interval is greater than the width of the tunneling window.

5. The non-volatile memory device of claim 1, wherein the width of the tunneling window is less than about 0.14 μm or less.

6. The non-volatile memory device of claim 1, wherein the upper floating gate and the lower floating gate are electrically connected.

7. The non-volatile memory device of claim 1, further comprising a first impurity region formed in the semiconductor substrate and aligned in the region between the first lower floating gate and the second lower floating gate.

8. The non-volatile memory device of claim 1, wherein the tunneling insulating layer has a thickness smaller than the gate insulating layer.

9. The non-volatile memory device of claim 1, wherein the tunneling insulating layer has a thickness of about 5 to about 100 angstroms (Å).

10. The non-volatile memory device of claim 1, wherein the lateral profiles of the lower floating gate, the upper floating gate, and the inter-gate insulating layer are substantially the same as the lateral profile of the control line.

11. The non-volatile memory device of claim 1, further comprising a select transistor formed spaced a predetermined interval apart from the memory transistor by on the gate insulating layer.

12. The non-volatile memory device of claim 7, further comprising:
a second impurity region spaced a predetermined interval apart from the first impurity region and aligned at a sidewall of the memory transistor in the semiconductor substrate; and
a third impurity region spaced a predetermined interval apart from the first impurity region and aligned at a sidewall of the select transistor in the semiconductor substrate.

13. The non-volatile memory device of claim 12, wherein the second impurity region has a lightly doped drain (LDD) structure and the third impurity region has a double diffused drain (DDD) structure.

14. A non-volatile memory device comprising:
a gate insulating layer having a tunnel window formed therein, said tunneling window having a predetermined width parallel to a channel length direction and having a predetermined length perpendicular to the channel length direction on a semiconductor substrate;
a lower floating gate having an opening which has a predetermined length parallel to a direction of the length of the tunneling window and partially exposes the tunneling window and a portion of the gate insulating layer which is adjacent to the tunneling window;
a tunneling insulating layer formed on the tunneling window exposed by the opening;
an upper floating gate which is formed on the lower floating gate and the tunneling insulating layer and fills the opening;
an inter-gate insulating layer formed on the upper floating gate; and
a memory transistor including a control line formed on the inter-gate insulating layer.

15. The non-volatile memory device of claim 14, wherein a length of the opening is greater than a width of an active region of the semiconductor substrate.

16. The non-volatile memory device of claim 14, wherein the width of the opening is substantially the same as a width of the tunneling window.

17. The non-volatile memory device of claim 14, wherein the width of the opening is greater than the width of the tunneling window and the opening has an inclined surface with a predetermined angle.

18. The non-volatile memory device of claim 14, further comprising a blocking insulating layer which is formed at sidewalls of the opening and defines a contact area between the semiconductor substrate and the lower floating gate, wherein the width of the opening is greater than the width of the tunneling window.

19. The non-volatile memory device of claim 14, wherein the width of the tunneling window is less than about 0.14 μm or less.

20. The non-volatile memory device of claim 14, wherein the upper floating gate and the lower floating gate are electrically connected to each other.

21. The non-volatile memory device of claim 14, further comprising a first impurity region formed in the semiconductor substrate and aligned in the region between the first lower floating gate and the second lower floating gate.

22. The non-volatile memory device of claim 14, wherein the tunneling insulating layer has a thickness smaller than the gate insulating layer.

23. The non-volatile memory device of claim 14, wherein the tunneling insulating layer has a thickness of about 5 to about 100 angstroms (Å).

24. The non-volatile memory device of claim 14, wherein the lateral profiles of the lower floating gate, the upper floating gate, and the inter-gate insulating layer are substantially the same as the lateral profile of the control line.

25. The non-volatile memory device of claim 14, further comprising a select transistor spaced a predetermined interval apart from the memory transistor on the gate insulating layer.

26. The non-volatile memory device of claim 21, further comprising:
a second impurity region separated from the first impurity region by a predetermined interval and aligned at a sidewall of the memory transistor in the semiconductor substrate; and
a third impurity region spaced a predetermined interval apart from the first impurity region and aligned at a sidewall of the select transistor in the semiconductor substrate.

27. The non-volatile memory device of claim 26, wherein the second impurity region has a lightly doped drain (LDD) structure and the third impurity region has a double diffused drain (DDD) structure.

28. A method of manufacturing a non-volatile memory device, the method comprising:
forming a gate insulating layer that provides a tunneling window with a region having a predetermined width parallel to a channel length direction and having a predetermined length perpendicular to the channel length direction on a semiconductor substrate;
forming a first-conductive-layer pattern on the gate insulating layer including a first-conductive-layer first pattern and a first-conductive-layer second pattern that are separated from each other by a predetermined interval to partially expose the region in which the tunneling window is to be formed and a portion of the gate insulating layer which is adjacent to the region;
forming a first impurity region in a region between the first-conductive-layer first pattern and the first-conductive-layer second pattern on the semiconductor substrate;
forming the tunneling window by selectively removing the gate insulating layer in the region in which the tunneling window is to be formed from the portion of the gate insulating layer exposed between the first-conductive-layer first pattern and the first-conductive-layer second pattern;
forming the tunneling insulating layer on the tunneling window;
forming a second conductive layer on the first-conductive-layer pattern and the tunneling insulating layer to fill the region between the first-conductive-layer first pattern and the first-conductive-layer second pattern;
patterning the first-conductive-layer pattern and the second conductive layer in a channel length direction;
forming a third conductive layer that is insulated from the first-conductive-layer pattern and the second conductive layer; and
forming a lower floating gate, an upper floating gate, and a control line by patterning the first-conductive-layer pattern, the second conductive layer, and the third conductive layer in a direction perpendicular to the channel length direction.

29. The method of claim 28, wherein the predetermined interval is substantially the same as a width of the tunneling window.

30. The method of claim 28, wherein the predetermined interval is greater than the width of the tunneling window and the region between the first-conductive-layer first pattern and first-conductive-layer second pattern has an inclined surface with a predetermined angle.

31. The method of claim 28, further comprising a blocking insulating layer which is formed at sidewalls of the region between the first-conductive-layer first pattern and first-conductive-layer second pattern and defines a contact area between the semiconductor substrate and the lower floating gate, and wherein the predetermined interval is greater than the width of the tunneling window.

32. The method of claim 28, wherein the width of the tunneling window is less than about 0.14 μm or less.

33. The method of claim 28, wherein the upper floating gate and the lower floating gate are electrically connected to each other.

34. The method of claim 28, wherein the formation of the tunneling window comprises:
forming a photoresist pattern that is patterned by an interval that is substantially the same as the length of a tunneling window on the gate insulating layer and the first-conductive-layer pattern; and
forming a region in which the tunneling window is to be formed by etching a portion of the gate insulating layer using the photoresist pattern as an etching mask.

35. The method of claim 28, wherein the formation of the tunneling window comprises:
forming a photoresist pattern having an opening with a length greater than the width of the tunneling window on the gate insulating layer and the first-conductive-layer pattern; and
forming the tunneling window by etching a portion of the gate insulating layer using the photoresist pattern as an etching mask.

36. The method of claim 35, wherein the width of the opening is substantially the same as a length of the tunneling window.

37. The method of claim 28, further comprising forming an inter-gate insulating layer on the second conductive layer before patterning the first-conductive-layer pattern and the second conductive layer in the channel length direction.

38. The method of claim 19, wherein in the formation of the first impurity region, the first impurity region is aligned in a region between the first-conductive-layer first pattern and the first-conductive-layer second pattern on the semiconductor substrate.

39. The method of claim 28, wherein the tunneling insulating layer has a thickness smaller than the gate insulating layer.

40. The method of claim 28, wherein the tunneling insulating layer has a thickness of about 5 to about 100 angstroms (Å).

41. The method of claim 28, further comprising a select transistor spaced a predetermined interval apart from the memory transistor on the gate insulating layer.

42. The method of claim 28, further comprising:
a second impurity region spaced a predetermined interval apart from the first impurity region and aligned at a sidewall of the memory transistor in the semiconductor substrate; and
a third impurity region spaced a predetermined interval apart from the first impurity region and aligned at a sidewall of the select transistor in the semiconductor substrate.

43. The method of claim 42, wherein the second impurity region has a lightly doped drain (LDD) structure and the third impurity region has a double diffused drain (DDD) structure.
